(19) United States
(12) Patent Application Publication
(10) Pub. No.: US 2013/0344698 A1
(43) Pub. Date: Dec. 26, 2013

(54) PATTERN FORMATION METHOD

(71) Applicant: KABUSHIKI KAISHA TOSHIBA, Tokyo (JP)

(72) Inventors: Shunsuke OCHIAI, Kanagawa (JP); Hisataka HAYASHI, Kanagawa (JP); Yusuke KASAHARA, Kanagawa (JP)

(73) Assignee: Kabushiki Kaisha Toshiba, Tokyo (JP)

(21) Appl. No.: 13/784,232

(22) Filed: Mar. 4, 2013

(30) Foreign Application Priority Data
Jun. 25, 2012 (JP) 2012-142527

(51) Int. Cl. H01L 21/302

(52) U.S. Cl. CPC H01L 21/302
USPC 438/694

(57) ABSTRACT

According to one embodiment, a mask layer is formed on a film to be processed. A resist film containing a desired pattern is formed on the mask layer. Etching is performed on the above mentioned mask layer with an etching gas that does not contain fluorine. The method also includes removing the resist film. After the resist film is removed, using the mask layer as a mask, an etching is performed on the to be processed film using a fluorocarbon gas.

### CROSS-REFERENCE TO RELATED APPLICATION

This application is based upon and claims the benefit of priority from Japanese Patent Application No. 2012-142527, filed Jun. 25, 2012; the entire contents of which are incorporated herein by reference.

### FIELD

Embodiments described herein relate to a pattern formation method.

### BACKGROUND

Recently, semiconductor integrated circuits are used in high integration, high-performance technology. Low cost pattern transfer methods of semiconductor integrated circuits include a RMAP (Resist Mask Process) structure laminated with a film to be processed, a BARC film and a resist film. The resist film is used as a mask to form a pattern in a film to be processed, and an etching process is conducted in a state where it has a selection ratio between the resist film and the film to be processed, by using an etching gas such as fluorocarbon gas, etc.

However, when the etching gas containing fluorine such as fluorocarbon is used, the resist film is fluorinated and the residue accumulates on the surface of the resist film, which deforms the resist film. In this case, it becomes difficult to transfer the pattern of the resist film that is to be used as the pattern for the film to be processed.

### DESCRIPTION OF THE DRAWINGS

FIGS. 1A to 1E are cross-sectional diagrams showing a pattern formation method according to a first embodiment.

### DETAILED DESCRIPTION

Embodiments of the invention provide a pattern formation method that can be transferred to a film accurately and process the film accurately.

In general, according to one embodiment, a pattern formation method according to this embodiment will be explained below in details with reference to the drawings. Furthermore, this invention is not limited to this embodiment.

To solve the above mentioned problem, a film to be processed (first film) is formed on a substrate. A mask layer (second film) is formed on the film to be processed in the pattern formation method of this embodiment. A resist layer containing a desired pattern is formed on the above mentioned mask layer. Etching is performed on the above mentioned mask layer using an etching gas that does not use fluorine. The above mentioned resist layer is removed. After removing the resist layer, the above mentioned mask layer is made as a mask, and etching is performed on the above mentioned film to be processed using fluorocarbon gas.

### First Embodiment

A pattern formation method according to the first embodiment will be explained below.

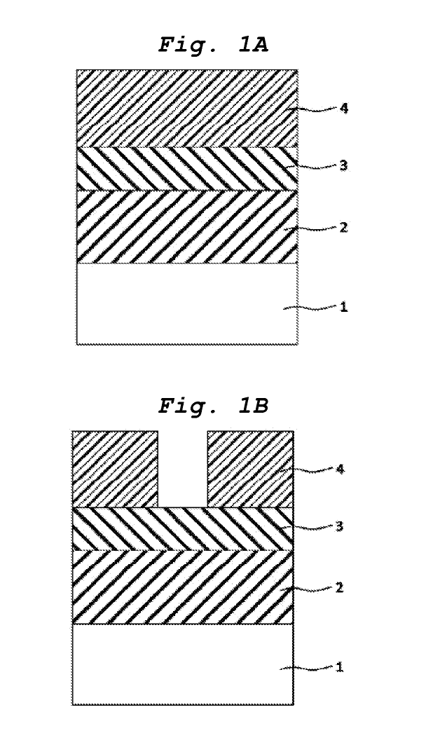

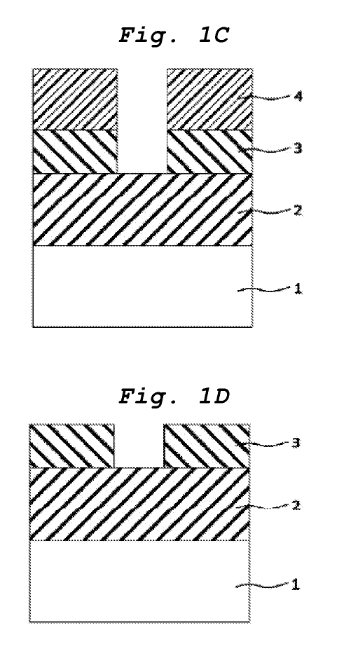

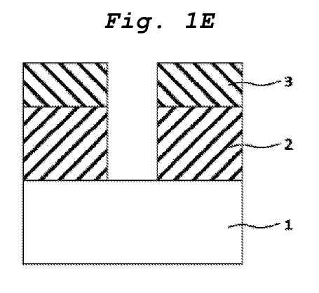

FIGS. 1A to 1E are diagrams showing a pattern formation method according to the first embodiment.

As a film to be processed 2, a silicon dioxide film, an oxidized film in which TEOS (Tetraethyl Orthosilicate) is used as the ingredient are formed on a semiconductor substrate 1. The film to be processed 2 can be various films such as metal films, not to be limited to only an oxidized film. The thickness of a film to be processed 2 is, for example, about 230 nm.

After the above mentioned process is over, a mask layer 3 is formed on the film to be processed 2. The mask layer 3 is used as a mask while performing etching on the film to be processed 2, which will be mentioned later. On the mask layer 3, an anti-reflection film, for example, an organic Bottom Anti-Reflection Coating (BARC) is used. Used in this organic BARC film are, for example, resins having an acrylic structure, an ester structure, or a poly hydroxy styrene structure, a structure for appropriately absorbing light with respect to an exposure wavelength, or resins including these copolymers or mixed resins. A BARC film may be selected from those having preferable exposure process margin of a resist, resist profile, shielding effects from the underlying substrate, or outgassing performance. Polyester-based resins for the BARC film may be used. In this way, it is possible to avoid fluorination of the mask layer 3 by performing etching using fluorocarbon gas, which will be mentioned later. The thickness of the organic BARC film used as the mask layer 3 is, for example, about 60 nm.

Next, a resist film 4 is coated on the mask layer 3. After that, etching is performed on the resist film 4 in a desired pattern by a lithography method. For example, the desired pattern of the resist film 4 is a circular shape of 100 nanometers (nm) diameter formed by carrying out an argon fluorine (ArF) exposure and an image development on the resist film 4. The thickness of the resist film 4 is, for example, about 120 nm.

Next, using the resist film 4 as a mask, the mask layer 3 is etched using an etching gas that does not contain fluorine. An etching is performed by plasma etching that uses, for example, N₂, CO₂, CO, O₂ gases as an etching gas that does not contain fluorine. As will be mentioned later, deformation of the resist film 4 can be avoided by using an etching gas that does not use fluorine. Etching is performed by using, for example, a dual-frequency superimposed plasma etching device of high frequency (100 MegaHertz (MHz) and low frequency (13 MHz).

Then, the resist film 4 is removed by a wet treatment. After the removal of the resist film 4 with flashing in which O₂ gas is used, the wet treatment is done by immersing the semiconductor substrate 1 in cyclohexanone. Flashing is performed after removing the resist film 4 that has its surface improved by the plasma etching, so that the resist film 4 can be separated from the semiconductor substrate 1 with the help of wet treatment. The resist film 4 can be removed by the wet treatment using cyclohexanone, etc. without performing etching on the mask layer 3.

Next, using the mask layer 3 as the mask for the film to be processed 2, plasma etching is performed on the film to be processed 2 by, for example, RIE (Reactive Ion Etching). As the etching gas, it is preferred to use fluorocarbon gas having high selectivity for an oxidized film used as the mask layer 3 and the film to be processed 2, or the mixed gas of fluorocarbon gas and oxygen gas or argon gas. Used as the fluorocarbon gas are, for example, CF₄, CHF₃, CH₂F₂, CH₃F, C₂F₆, C₃F₈, C₄F₆, C₅F₈ or C₅HF₇; however in particular, it is preferred to use C₅HF₇ gas that has large selectivity with an anti-reflection film used as a mask layer 3. Moreover, the mixed gas prepared by combining these gases can also be used as the etching gas.

Conventionally, as a resist mask process, etching used to be performed on a film to be processed 2 using fluorocarbon gas with the resist film intact. In this conventional process, etching is carried out to the film to be processed 2 using both anti-reflection film and resist film as the mask. That is to say, etching used to be performed without removing the resist film.

However, when fluorocarbon gas is applied onto a resist film, H atoms in the resist film are substituted with F atoms, deforming the shape of the resist film caused by the stress generated in the resist film. If deformation occurs so as to contract the resist film, the upper surface of the anti-reflection film will be exposed.

Moreover, when etching is performed on a film to be processed using fluorocarbon gas, etching residue including C atoms, H atoms, O atoms, etc. generated by the etching reaction is attached to the anti-reflection film, protecting the etching of the anti-reflection film. However, as this etching residue is normally attached to the uppermost layer film, the residue is attached to the resist film in the conventional structure, the chances that it might be attached to the anti-reflection film are less and thus the anti-reflection film could not be protected from etching. Consequently, etching could be easily performed on a shoulder part, which is the intersection of the upper surface and the side surface of the anti-reflection film, making it difficult to accurately transfer a pattern to the film to be processed.

In contrast to this, according to the pattern formation method according to embodiments described herein, etching is performed on the film to be processed 2 using fluorocarbon gas after the removal of the resist film 4. As the resist film 4 is not there, etching residue can be attached to the mask layer 3 easily, and etching of the mask layer 3 is protected. Consequently, pattern formation of the mask layer 3 can be accurately carried out, and the pattern can be transferred to the film to be processed 2.

As has been described above, the given pattern formed on the resist film 4 is transferred accurately to the film to be processed 2, and contact holes with a high aspect ratio can be formed in the film to be processed 2.

Furthermore, the pattern formation method of this embodiment can be used, for example, to form a contact hole to contact the semiconductor substrate 1, but it is not limited thereto.

Moreover, this invention is not limited to the above mentioned embodiment. Certainly, various changes can be additionally obtained in the range that does not affect the gist of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern formation method, comprising:
depositing a first film on a substrate;
forming a second film on the first film;
forming a resist film having a desired pattern on the second film;
etching the second film with an etching gas that does not contain fluorine using the resist film as a mask;
removing the resist film; and
etching the first film with a fluorocarbon gas using the second film as a mask, after the resist film is removed.

2. The pattern formation method of claim 1, wherein the second film comprises an anti-reflection film.

3. The pattern formation method of claim 2, wherein the anti-reflection film comprises a polyester.

4. The pattern formation method of claim 2, wherein removal of the resist film comprises exposing the resist film to cyclohexanone.

5. The pattern formation method of claim 1, wherein the fluorocarbon gas includes C₅HF₇.

6. The pattern formation method of claim 5, wherein the second film comprises an anti-reflection film.

7. The pattern formation method of claim 6, wherein the anti-reflection film comprises a polyester.

8. The pattern formation method of claim 5, wherein removal of the resist film comprises exposing the resist film to cyclohexanone.

9. A pattern formation method comprising:
forming a mask layer on a film to be processed;
forming a resist film having a desired pattern on the mask layer;
etching the mask layer with an etching gas that does not contain fluorine using the resist film as a mask;
removing the resist film; and
etching the film to be processed with a fluorocarbon gas using the mask layer as a mask, after the resist film is removed.

10. The pattern formation method of claim 9, wherein the mask layer comprises an anti-reflection film.

11. The pattern formation method of claim 10, wherein removal of the resist film comprises exposing the resist film to cyclohexanone.

12. The pattern formation method of claim 10, wherein the anti-reflection film comprises a polyester.

13. The pattern formation method of claim 12, wherein removal of the resist film comprises exposing the resist film to cyclohexanone.

14. The pattern formation method of claim 9, wherein the fluorocarbon gas includes C₅HF₇.

15. The pattern formation method of claim 14, wherein removal of the resist film comprises exposing the resist film to cyclohexanone.

16. The pattern formation method of claim 14, wherein the mask layer comprises an anti-reflection film.

17. The pattern formation method of claim 16, wherein the anti-reflection film comprises a polyester.

18. A pattern formation method, comprising:
forming a film to be processed on a substrate;
forming a mask layer on the film to be processed;
forming a resist film having a desired pattern on the mask layer;
etching the mask layer with an etching gas that does not contain fluorine using the resist film as a mask;
removing the resist film; and
forming features in the film to be processed using the mask layer as a mask by etching the film to be processed with a fluorocarbon gas after the resist film is removed.

19. The pattern formation method of claim 18, wherein removal of the resist film comprises exposing the resist film to cyclohexanone.

20. The pattern formation method of claim 18, wherein the mask layer comprises an anti-reflection film.
